(19) United States
(12) Patent Application Publication
(10) Pub. No.: US 2026/0271600 A1
(43) Pub. Date: Sep. 10, 2026

(54) DISPLAY DEVICE, ELECTRONIC DEVICE, AND METHOD FOR MANUFACTURING THE DISPLAY DEVICE

(71) Applicant: Samsung Display Co., LTD., Yongin-si (KR)

(72) Inventors: HYEONBUM LEE, Yongin-si (KR); HYUNHO KIM, Yongin-si (KR); HYOENG-KI KIM, Yongin-si (KR); KEUNKYU SONG, Yongin-si (KR)

(21) Appl. No.: 19/331,411

(22) Filed: Sep. 17, 2025

(30) Foreign Application Priority Data
Mar. 4, 2025 (KR) 10-2025-0027285

(51) Int. Cl. H10K 59/80; H10K 59/12; H10K 102/10

(52) U.S. Cl. CPC H10K 59/8792; H10K 59/1201; H10K 59/80521; H10K 2102/103

(57) ABSTRACT

A display device includes a substrate, a circuit layer disposed on the substrate, a light-emitting diode layer, an encapsulation layer, and a light-shielding unit. The light-emitting diode layer is disposed on the circuit layer and includes a first emission layer and a second emission layer corresponding, respectively, to a first pixel unit and a second pixel unit. The encapsulation layer is disposed on the light-emitting diode layer and includes at least one of an inorganic film and an organic film. The light-shielding unit is disposed on the encapsulation layer, overlaps the second pixel unit, and exposes a light-emitting region of the second pixel unit. The light-emitting diode layer further includes a first anode electrode, a first cathode electrode, a second anode electrode, and a second cathode electrode. The first cathode electrode has a higher transmittance than a transmittance of the second cathode electrode.

### RELATED APPLCATION

This application claims priority to Korean Patent Application No. 10-2025-0027285, filed on Mar. 4, 2025, and all the benefits accruing therefrom under 35 U.S.C. §119, the content of which in its entirety is herein incorporated by reference.

### BACKGROUND

### Field

The disclosure relates to a display device and a method for manufacturing the same, and more particularly, to a display device capable of operating in a privacy protection mode with enhanced viewing angle luminance characteristics, and a method for manufacturing the same.

### Description of the Related Art

Display devices visually present data on a screen to convey information to users. Recently, privacy protection modes—also referred to as private modes—are being provided in environments where protecting personal information is crucial, such as in public spaces or multi-user facilities, to prevent user screens from being exposed. The private mode may be driven by controlling the luminance of predetermined pixels such that the luminance as viewed from the side is lower than that as viewed from the front. As a result, luminance characteristics and visibility may vary depending on the viewing angle from the front versus the side. To implement the private mode in a display device, a black matrix may be disposed over predetermined pixels, thereby limiting the viewing angle from the side when the private mode is active.

### SUMMARY

However, due to this structural characteristic, the viewing angle characteristics from the side may also deteriorate in a normal mode—where all pixels are driven—not just in the private mode. Thus, there may be an issue where the display quality is degraded compared to a display device that does not support the private mode.

Contrived to address the foregoing issues, the disclosure is directed to providing a display device and a method for manufacturing the same that support a private mode with improved luminance characteristics relative to the viewing angle. Specifically, the disclosure provides a display device and a method for manufacturing the same in which cathode electrodes with different optical properties are applied respectively to a normal pixel region and a private pixel region.

A display device in an embodiment of the disclosure includes a substrate, a circuit layer, a light-emitting diode layer, an encapsulation layer, and a light-shielding unit. The circuit layer is disposed on the substrate. The light-emitting diode layer is disposed on the circuit layer and includes a first emission layer corresponding to a first pixel unit and a second emission layer corresponding to a second pixel unit. The encapsulation layer is disposed on the light-emitting diode layer and includes at least one of an inorganic film and an organic film. The light-shielding unit is disposed on the encapsulation layer, overlaps the second pixel unit, and exposes a light-emitting region of the second pixel unit. The light-emitting diode layer further includes a first anode electrode, a first cathode electrode, a second anode electrode, and a second cathode electrode. The first anode electrode corresponds to the first pixel unit and is disposed between the circuit layer and the first emission layer. The first cathode electrode corresponds to the first pixel unit and is disposed on the first emission layer. The second anode electrode corresponds to the second pixel unit and is disposed between the circuit layer and the second emission layer. The second cathode electrode corresponds to the second pixel unit and is disposed on the second emission layer. The first cathode electrode has a higher transmittance than a transmittance of the second cathode electrode.

In an embodiment, the first cathode electrode may include at least one of indium tin oxide (“ITO”), indium zinc oxide (“IZO”), zinc oxide (ZnO), aluminum-doped zinc oxide (“AZO”), and indium oxide (In₂O₃).

In an embodiment, the second cathode electrode may include at least one of silver (Ag) and magnesium (Mg).

In an embodiment, the viewing angle of the first pixel unit may be wider than the viewing angle of the second pixel unit.

In an embodiment, an opening that exposes the light-emitting region of the second pixel unit may be defined in the light-shielding unit. The opening of the light-shielding unit may have a shape including at least one of circular, elliptical, and polygonal shapes.

In an embodiment, the light-shielding unit may include a plurality of light-shielding patterns stacked in a direction of display.

In an embodiment of the disclosure, an electronic device includes a display module. The display module includes a display panel and a driving circuit. The display panel includes a first pixel unit and a second pixel unit. The driving circuit is electrically connected to the first and second pixel units. The driving circuit activates the first and second pixel units in a first operation mode and to deactivate the first pixel unit and activate the second pixel unit in a second operation mode. The first pixel unit includes a first anode electrode, a first emission layer, and a first cathode electrode. The second pixel unit includes a second anode electrode, a second emission layer, and a second cathode electrode. The first cathode electrode has a higher transmittance than a transmittance of the second cathode electrode.

In an embodiment, the first cathode electrode may include at least one of indium tin oxide (“ITO”), indium zinc oxide (“IZO”), zinc oxide (ZnO), aluminum-doped zinc oxide (“AZO”), and indium oxide (In₂O₃).

In an embodiment, the second cathode electrode may include at least one of silver (Ag) and magnesium (Mg).

In an embodiment, the viewing angle of the first pixel unit may be wider than the viewing angle of the second pixel unit.

In an embodiment, the first and second pixel units may be alternately arranged two-dimensionally and define a display region of the display panel.

In an embodiment, the electronic device may further include a processor, a memory, and a power module. The processor may execute an application to transfer an image data signal to the display module. The memory may have data information for executing the application stored therein. The power module may supply power to the display module, the processor, and the memory. The display module may output image information based on the image data signal.

In an embodiment of the disclosure, a method for manufacturing a display device may includes forming an emission layer, forming a first cathode electrode, forming a second cathode electrode, forming an encapsulation layer, and forming a light-shielding pattern.

In the forming the emission layer, an anode electrode and an emission layer may be formed on a display region of a circuit layer. In the forming the first cathode electrode, a first cathode electrode may be formed on the emission layer corresponding to a first region of the display region. In the forming the second cathode electrode, a second cathode electrode may be formed on the emission layer corresponding to a second region of the display region, the second region being different from the first region.

In the forming the encapsulation layer, at least one of an inorganic film and an organic film may be formed on the first and second cathode electrodes. In the forming the light-shielding pattern, a light-shielding pattern may be formed on the encapsulation layer, the light-shielding pattern overlapping the second region and exposing a light-emitting region of the second region. The first cathode electrode may have a higher transmittance than a transmittance of the second cathode electrode.

In an embodiment, the forming the first cathode electrode may include depositing a first cathode electrode including or consisting of at least one of indium tin oxide (“ITO”), indium zinc oxide (“IZO”), zinc oxide (ZnO), aluminum-doped zinc oxide (“AZO”), and indium oxide (In₂O₃).

In an embodiment, the forming the second cathode electrode may include depositing a second cathode electrode including or consisting of at least one of silver (Ag) and magnesium (Mg).

In an embodiment, the forming the first cathode electrode may be performed before the forming the second cathode electrode. In another embodiment, the forming the second cathode electrode may be performed before the forming the first cathode electrode.

In an embodiment, the first and second regions may be alternately arranged two-dimensionally in the display region.

In an embodiment, an opening that exposes the light-emitting region of the second region may be defined in the light-shielding pattern. The opening of the light-shielding pattern may have a shape including at least one of circular, elliptical, and polygonal shapes.

In an embodiment, the viewing angle of the first region may be wider than the viewing angle of the second region.

In an embodiment of the disclosure, since only private pixels having a limited viewing angle are driven in a private mode, the visibility of the display device may vary depending on the viewing angle.

In addition, in an embodiment of the disclosure, by forming a cathode electrode including or consisting of silver (Ag) or magnesium (Mg) in a private pixel region and by forming a cathode electrode including or consisting of a transparent conductive oxide (“TCO”) in a normal pixel region, the viewing angle characteristics may be improved when the display device is driven in a normal mode.

### BRIEF DESCRIPTION OF THE DRAWINGS

These and/or other features will become apparent and more readily appreciated from the following description of the embodiments, taken in conjunction with the accompanying drawings in which:

FIG. 1 illustrates an embodiment of operation modes of a display device according to the disclosure;

FIG. 2 is a plan view of an embodiment of a display device according to the disclosure;

FIG. 3 is a schematic plan view of an embodiment of a display device according to the disclosure;

FIG. 4 illustrates an equivalent circuit diagram of a pixel shown in FIG. 3;

FIG. 5 illustrates a cross-sectional view of a display device taken along line I–I′ of FIG. 2;

FIG. 6 illustrates an enlarged plan view of an embodiment of a pixel shown in FIG. 2 according to the disclosure;

FIG. 7A illustrates an enlarged plan view of an embodiment of a pixel shown in FIG. 2 in a normal mode according to the disclosure;

FIG. 7B illustrates an enlarged plan view of an embodiment of a pixel shown in FIG. 2 in a private mode according to the disclosure;

FIG. 8 illustrates a cross-sectional view of a display panel taken along line II–II′ of FIG. 6;

FIG. 9 is a schematic illustration of a viewing angle of an embodiment of a display device according to the disclosure;

FIG. 10 is a flow diagram illustrating an embodiment of a method for manufacturing a display device according to the disclosure;

FIGS. 11A through 11E are diagrams illustrating an embodiment of a method for manufacturing a display device according to the disclosure;

FIG. 12 is a graph showing luminance variation according to a viewing angle of an embodiment of a display device according to the disclosure;

FIG. 13 is a block diagram of an embodiment of an electronic device including a display device according to the disclosure; and

FIG. 14 illustrates various embodiments of electronic devices including a display device according to the disclosure.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described herein, by referring to the drawing figures, to explain features of the disclosure. When an element (or region, layer, portion, or the like) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. If one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, characteristics, and the like illustrated in the drawings.

Terms such as “first” and “second” may be used in describing various elements, but the elements shall not be restricted to the terms. The terms may be used to distinguish one element from the other. For instance, the first element may be named the second element, and vice versa, without departing the scope of claims of the disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” and the like may be used herein to describe one element’s relationship to another element as illustrated in the accompanying drawing figures. It shall be understood that relative terms are intended to encompass different orientations of the device in addition to the orientation depicted in the accompanying drawing figures. For example, if the device in one of the drawing figures is turned over, elements described as being on the “lower” side of the other elements would then be oriented on “upper” sides of the other elements. The example term “lower” may therefore encompass an orientation of both “lower” and “upper,” depending on the particular orientation of the figure. Similarly, if the device in one of the drawing figures is turned over, elements described as “below” or “beneath” other elements would then be oriented “above” the other elements. The example term “below” or “beneath” may therefore encompass an orientation of both above and below.

An expression such as “comprising” or “including” is intended to designate a characteristic, a number, a step, an operation, an element, a part, or combinations thereof, and shall not be construed to preclude any possibility of presence or addition of one or more other characteristics, numbers, steps, operations, elements, parts or combinations thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms, including technical terms and scientific terms, used herein have the same meaning as how they are generally understood by those of ordinary skill in the art to which the disclosure pertains. Any term that is defined in a general dictionary shall be construed to have the same meaning in the context of the relevant art, and, unless otherwise defined explicitly, shall not be interpreted to have an idealistic or excessively formalistic meaning.

In the specification, when any embodiment may be differently implemented, the specified order of process may be performed differently than the described order. In an embodiment, two processes described to be performed sequentially may be performed simultaneously or performed in a reverse order, for example.

In the disclosure, for the purpose of describing a display device in an embodiment, first through third directions DR1, DR2, DR3 may be defined. The display device includes a display panel, and the display panel is formed to include pixels on a plane defined by the first direction DR1 and the second direction DR2. The third direction DR3 is defined as the thickness direction of the display panel, and the first through third directions DR1, DR2, DR3 may be mutually orthogonal.

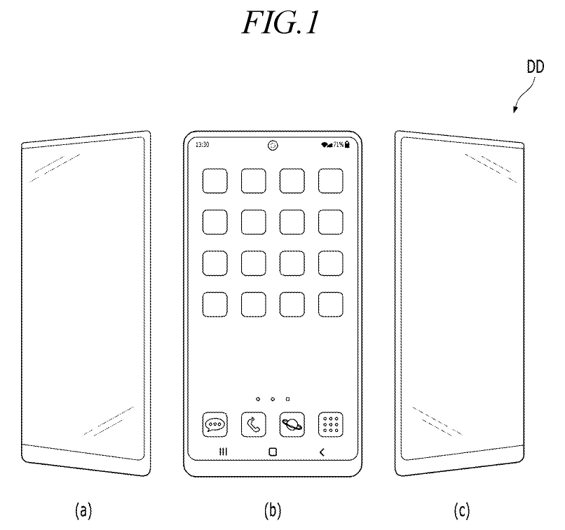

FIG. 1 illustrates an embodiment of operation modes of a display device according to the disclosure. The display device DD may operate in a private mode or a normal mode. The display device DD may operate to have general viewing angle characteristics in the normal mode and to have a limited viewing angle in the private mode, where side visibility and luminance are reduced.

FIG. 1 shows viewing angle characteristics of the display device DD when operating in the private mode. Referring to the part indicated with “(a)” and the part indicated with “(c)” in FIG. 1, when the display device DD operates in the private mode, it may be difficult for a user to recognize the display screen from a side view. Referring to the part indicated with “(b)” in FIG. 1, the user may still recognize the display screen from the front view even when the display device DD is operating in the private mode. When the display device DD is in the normal mode, unlike the part indicated with “(a)” and the part indicated with “(c)” in FIG. 1, the user may view the display screen even from the side, as shown in the part indicated with “(b)” in FIG. 1.

Accordingly, when a third party, other than the user, views the display device DD from the side, operation in the private mode may prevent the user’s screen from being exposed. The private mode may thus function as a privacy protection mode. How the display device DD is driven in the private mode and the normal mode will be described later.

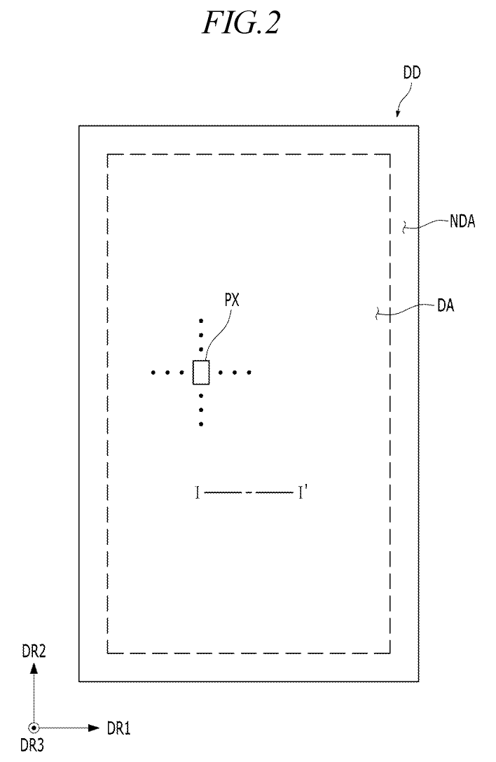

FIG. 2 is a plan view of an embodiment of a display device according to the disclosure. Referring to FIG. 2, the display device DD may include a display panel (not shown), and the display panel may have a display region DA and a non-display region NDA defined therein. The display region DA may be an area where images are displayed and may include a plurality of pixels PX arranged therein, the pixels PX including light-emitting diodes such as organic light-emitting diodes for rendering images. Each pixel PX may include a thin-film transistor configured to control the light-emitting diodes. A single pixel PX may include at least one thin-film transistor. The non-display region NDA may surround the display region DA and may have a shape disposed outside the display region DA.

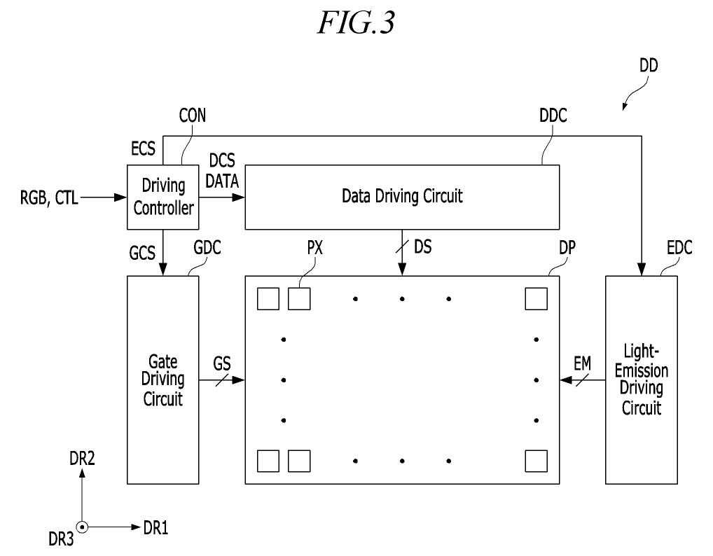

FIG. 3 is a schematic plan view of an embodiment of a display device according to the disclosure. Referring to FIG. 3, the display device DD includes a display panel DP, a gate driving circuit GDC, a light-emission driving circuit EDC, a data driving circuit DDC, and a driving controller CON. The display device DD is not limited to what is illustrated in FIG. 3 and may further include additional components. In an embodiment, the display device DD may further include a voltage generator for generating voltages desired by components including the display panel DP, for example.

The driving controller CON receives an image signal RGB and a control signal CTL. In an embodiment, the image signal RGB and the control signal CTL may be provided from an application processor (not shown), for example. It shall be understood that the image signal RGB is a graphical source of an image to be displayed on the display panel DP. The control signal CTL may include a synchronization signal for aligning image output with the correct positions on the display panel DP.

The driving controller CON generates an image data signal DATA by converting a data format of the image signal RGB to match an interface specification of the data driving circuit DDC. The driving controller CON is also configured to generate a gate control signal GCS for controlling the gate driving circuit GDC, a light-emission drive control signal ECS for controlling the light-emission driving circuit EDC, and a data control signal DCS for controlling the data driving circuit DDC, based on the control signal CTL.

The display panel DP includes pixels PX two-dimensionally arranged on a plane defined by a first direction DR1 and a second direction DR2. The display panel DP is electrically connected to the gate driving circuit GDC via gate lines and to the light-emission driving circuit EDC via emission control lines. The gate lines and the emission control lines may extend in the first direction DR1. The display panel DP is also electrically connected to the data driving circuit DDC via data lines, which may extend in the second direction DR2.

The data driving circuit DDC receives the data control signal DCS and the image data signal DATA from the driving controller CON. The data driving circuit DDC may be further configured to convert the image data signal DATA, which is a digital signal, into data signals DS in analog format. The data signals DS are converted to correspond to a grayscale value of the image data signal DATA. The data driving circuit DDC may output the converted data signals DS to the pixels PX through a plurality of data lines.

The gate driving circuit GDC receives the gate control signal GCS from the driving controller CON. Based on the gate control signal GCS, the gate driving circuit GDC may output gate signals GS to the gate lines. The gate driving circuit GDC may sequentially activate the pixels PX on a row-by-row basis via the gate signals GS. Here, the term “activate” refers to a state in which the pixels PX are enabled to receive the data signals DS through the data lines.

The light-emission driving circuit EDC receives the light-emission drive control signal ECS from the driving controller CON. Based on the light-emission drive control signal ECS, the light-emission driving circuit EDC GDC may output emission control signals EM to the emission control lines. The light-emission driving circuit EDC may sequentially cause the pixels PX to emit light on a row-by-row basis via the emission control signals EM.

The display device DD may activate or deactivate a first pixel and a second pixel arranged on the display panel DP through the gate driving circuit GDC, the light-emission driving circuit EDC, the data driving circuit DDC, and the driving controller CON. The first pixel may be a private pixel having a limited viewing angle for implementing a private mode. The private pixel may exhibit lower luminance when viewed from a side than when viewed from the front. The second pixel may be a normal pixel having an unrestricted viewing angle.

The display device DD may operate in a normal mode by activating both the first and second pixels in a first operation mode through the gate driving circuit GDC, the light-emission driving circuit EDC, the data driving circuit DDC, and the driving controller CON. In a second operation mode, the display device DD may operate in a private mode by activating the first pixel and deactivating the second pixel. Accordingly, in the private mode, only the first pixel is activated, and a display screen with a limited viewing angle may be presented. The first and second operation modes may be controlled via a mode control signal configured to switch between the private mode and the normal mode, allowing for respective mode transitions.

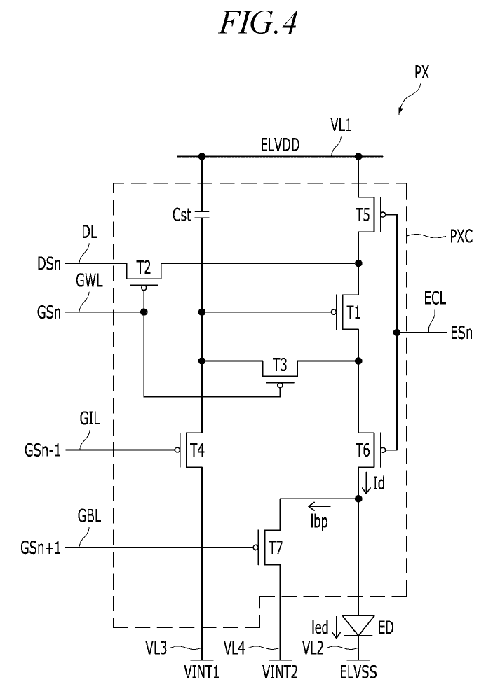

FIG. 4 is an equivalent circuit diagram of a pixel shown in FIG. 3. Referring to FIG. 4, a pixel PX is electrically connected to a data line DL, gate lines GWL, GIL, GBL (hereinafter referred to as a first gate line GIL, a second gate line GWL, and a third gate line GBL), and emission control lines ECL. The pixel PX corresponds to each of the plurality of pixels PX illustrated in FIG. 3.

The pixel PX receives a first driving voltage ELVDD, a second driving voltage ELVSS, a first initialization voltage VINT1, and a second initialization voltage VINT2. Although not depicted, the first driving voltage ELVDD, the second driving voltage ELVSS, the first initialization voltage VINT1, and the second initialization voltage VINT2 may be provided using voltages generated by a power management circuit of the display device DD.

The pixel PX includes a pixel circuit PXC and a light-emitting diode ED. The pixel circuit PXC includes first through seventh transistors T1 to T7 and one capacitor Cst. Each of the first through seventh transistors T1 to T7 may be a transistor having a low-temperature polycrystalline silicon (“LTPS”) semiconductor layer. However, the disclosure is not limited thereto, and the transistors may also be transistors having an oxide semiconductor as the semiconductor layer. In an alternative embodiment, at least one of the transistors T1 to T7 may be an N-type transistor while remaining (the other) transistors are P-type transistors. The circuit configuration and number of transistors in the pixel PX are illustrative and not limited to what is shown in FIG. 4, and the configuration of the pixel circuit PXC may be varied.

The first transistor T1 supplies a driving current Id to the light-emitting diode ED based on the magnitude of a data signal DSn. The second through seventh transistors T2 to T7 turn on or off such that the first transistor T1 receives the data signal DSn and supplies the driving current Id based on the magnitude of the data signal DSn. To this end, the gate electrodes of the transistors T2 to T7 are connected to one of the first gate line GIL, second gate line GWL, third gate line GBL, and the emission control lines ECL. A portion of the driving current Id bypasses through the seventh transistor T7 as a bypass current Ibp when the seventh transistor T7 is in an off-state.

The first transistor T1 includes a first electrode connected to a first driving voltage line VL1 via the fifth transistor T5, a second electrode electrically connected to the anode of the light-emitting diode ED via the sixth transistor T6, and a gate electrode connected to one end of the capacitor Cst. The first transistor T1 receives the data signal DSn transferred through the data line DL via a switching operation of the second transistor T2 and to supply the driving current Id to the light-emitting diode ED.

The second transistor T2 includes a first electrode connected to the data line DL, a second electrode connected to the first electrode of the first transistor T1, and a gate electrode connected to the second gate line GWL. The second transistor T2 turns on in response to a gate signal GSn (hereinafter referred to as the second gate signal) transferred through the second gate line GWL and to transfer the data signal DSn from the data line DL to the first electrode of the first transistor T1.

The third transistor T3 includes a first electrode connected to the gate electrode of the first transistor T1, a second electrode connected to the second electrode of the first transistor T1, and a gate electrode connected to the second gate line GWL. The third transistor T3 turns on in response to the second gate signal GSn transferred through the second gate line GWL and to interconnect the gate electrode and the second electrode of the first transistor T1 to form a diode connection of the first transistor T1.

The fourth transistor T4 includes a first electrode connected to the gate electrode of the first transistor T1, a second electrode connected to a third voltage line VL3 to which the first initialization voltage VINT1 is transferred, and a gate electrode connected to the first gate line GIL. The fourth transistor T4 turns on in response to a gate signal GSn-1 (hereinafter referred to as the first gate signal) transferred through the first gate line GIL and to perform an initialization operation by transferring the first initialization voltage VINT1 to the gate electrode of the first transistor T1 to reset the voltage at the gate electrode of the first transistor T1.

The fifth transistor T5 includes a first electrode connected to the first driving voltage line VL1, a second electrode connected to the first electrode of the first transistor T1, and a gate electrode connected to the emission control line ECL. The sixth transistor T6 includes a first electrode connected to the second electrode of the first transistor T1, a second electrode connected to the anode of the light-emitting diode ED, and a gate electrode connected to the emission control line ECL. The fifth and sixth transistors T5 and T6 turn on simultaneously in response to an emission control signal ESn transferred through the emission control line ECL. The first driving voltage ELVDD applied through the turned-on fifth transistor T5 is compensated via the first transistor T1 and transferred to the light-emitting diode ED.

The seventh transistor T7 includes a first electrode connected to a fourth voltage line VL4 to which the second initialization voltage VINT2 is transferred, a second electrode connected to the second electrode of the sixth transistor T6, and a gate electrode connected to the third gate line GBL. The seventh transistor T7 turns on in response to a gate signal GSn+1 (hereinafter referred to as the third gate signal) transferred through the third gate line GBL. The second initialization voltage VINT2 applied through the turned-on seventh transistor T7 may initialize the anode of the light-emitting diode ED.

One end of the capacitor Cst is connected to the gate electrode of the first transistor T1 as described above, and an opposite end is connected to the first driving voltage line VL1. The cathode of the light-emitting diode ED may be connected to a second driving voltage line VL2 that transfers the second driving voltage ELVSS.

The light-emitting diode ED may include a light-emitting material such as an organic light-emitting material, an inorganic light-emitting material, a quantum dot, or a quantum rod. The light-emitting diode ED may emit light based on a light-emission current Ied.

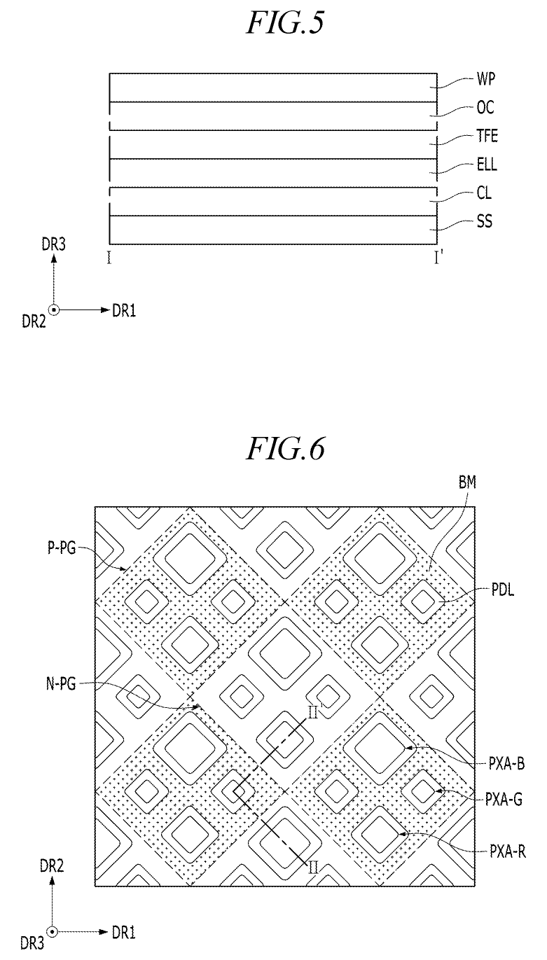

FIG. 5 is a cross-sectional view of an embodiment of a display device taken along line I–I′ of FIG. 2. Referring to FIG. 5, a display panel DP in an embodiment of the disclosure includes a substrate SS, a circuit layer CL, a light-emitting diode layer ELL, an encapsulation layer TFE, an overcoat layer OC, and a window layer WP, which may be sequentially stacked in a third direction DR3. However, the stacked structure of the display panel DP is not limited thereto and may further include additional components.

The substrate SS may include or consist of various materials such as glass, metal, or plastic. In an embodiment, the substrate SS may be a flexible substrate, for example.

The circuit layer CL is disposed on the substrate SS. The circuit layer CL may correspond to the pixel circuit PXC of FIG. 4. Although not depicted in FIG. 5, the circuit layer CL may include a buffer layer, a semiconductor layer, a gate insulating layer, a conductive layer, an inter-insulating layer, a circuit insulating layer, a planarization layer, or the like. The pixel circuit PXC, which includes the transistors T1 to T7 and the capacitor Cst shown in FIG. 4, is formed by these layers.

The light-emitting diode layer ELL is disposed on the circuit layer CL and may include a light-emitting diode and a pixel defining layer. The light-emitting diode may be an organic light-emitting diode, in which case the light-emitting diode may include an anode electrode, an emission layer, and a cathode electrode. The anode electrode may be electrically connected to a transistor disposed on the circuit layer CL through a contact hole. The pixel defining layer may at least partially overlap the anode electrode to partition the plurality of pixels. The pixel defining layer serves to define the pixels. The light-emitting diode layer ELL may additionally include a hole transport layer or an electron transport layer.

The encapsulation layer TFE is disposed on the light-emitting diode layer ELL and may include at least one of an inorganic encapsulation layer and an organic encapsulation layer. The encapsulation layer TFE may cover the light-emitting diode. The encapsulation layer TFE may protect the light-emitting diode layer ELL from external oxygen or moisture.

The overcoat layer OC is disposed on the encapsulation layer TFE and may include a planarization layer, a light-shielding unit, and a color filter. The overcoat layer OC may include a planarization layer on the light-shielding unit and the color filter to smooth step differences caused by the light-shielding unit and the color filter. The light-shielding unit may be a black matrix configured to block light without transmitting it. The color filter may be a light-transmitting optical filter configured to transmit light emitted from the light-emitting diode. The planarization layer may cover the light-shielding unit and the color filter.

The window layer WP is disposed on the overcoat layer OC and may be provided to protect the display device DD from external impact. The window layer WP may include an optically transparent insulating material so that light may be transmitted therethrough. In addition, the window layer WP may serve as an input surface for the user and may be formed through an adhesive process using a plastic film.

FIG. 6 is an enlarged plan view of an embodiment of a pixel PX shown in FIG. 2 according to the disclosure. Referring to FIG. 6, the display panel DP may include a private pixel unit P-PG and a normal pixel unit N-PG. The private pixel unit P-PG and the normal pixel unit N-PG may each include light-emitting regions PXA-R, PXA-G, and PXA-B. Each of the light-emitting regions PXA-R, PXA-G, and PXA-B may be a region from which light generated by an organic light-emitting diode is emitted and may correspond to a sub-pixel. Each of the light-emitting regions PXA-R, PXA-G, and PXA-B may be a region defined by a pixel defining layer PDL. The areas of the light-emitting regions PXA-R, PXA-G, and PXA-B may differ from one another, and the area ratios may differ from those illustrated in FIG. 6.

The private pixel unit P-PG and the normal pixel unit N-PG may be alternately arranged two-dimensionally in a plan view defined by the first direction DR1 and the second direction DR2, thereby defining a display region of the display panel DP. The private pixel unit P-PG may be distinguishable from the normal pixel unit N-PG in that a light-shielding unit BM is on the light-emitting diode layer. Openings that expose the light-emitting regions PXA-R, PXA-G, and PXA-B may be defined in the light-shielding unit BM. The openings of the light-shielding unit BM may have a shape including at least one of circular, elliptical, and polygonal shapes.

The display device DD in an embodiment of the disclosure may operate in a normal mode and a private mode. In the normal mode, both the private pixel unit P-PG and the normal pixel unit N-PG are activated, providing a wide viewing angle in all directions. In the private mode, the private pixel unit P-PG is activated and the normal pixel unit N-PG is deactivated, thereby providing light with reduced side visibility compared to the normal mode.

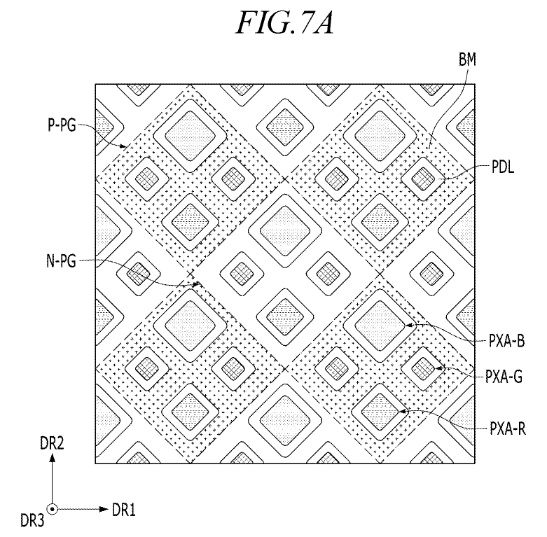

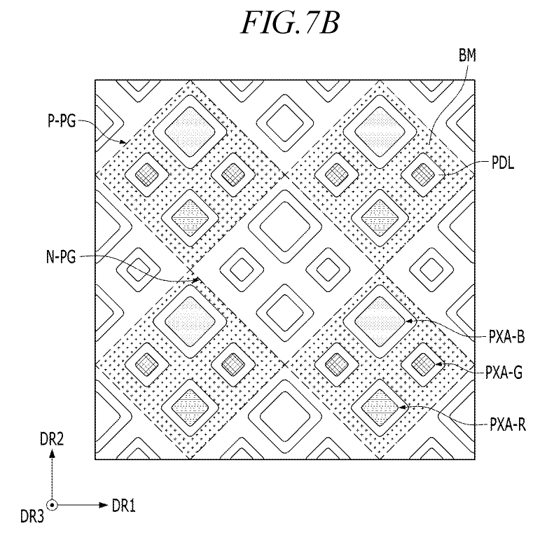

FIG. 7A is an enlarged plan view of an embodiment of a pixel shown in FIG. 2 in a normal mode according to the disclosure. Referring to FIG. 7A, as previously described, in the normal mode, both the private pixel unit P-PG and the normal pixel unit N-PG are activated, and light may be emitted from all of the light-emitting regions PXA-R, PXA-G, and PXA-B corresponding to the private pixel unit P-PG and the normal pixel unit N-PG. Accordingly, the display device DD may provide a wide viewing angle from both the front and the side.

FIG. 7B is an enlarged plan view of an embodiment of a pixel shown in FIG. 2 in a private mode according to the disclosure. Referring to FIG. 7B, in the private mode, the private pixel unit P-PG is activated and the normal pixel unit N-PG is deactivated, so that light may be emitted only from the light-emitting regions PXA-R, PXA-G, and PXA-B corresponding to the private pixel unit P-PG. As a result, the viewing angle from the side is more restricted compared to the normal mode, and visibility of the display screen may be reduced when the display device DD is viewed from the side.

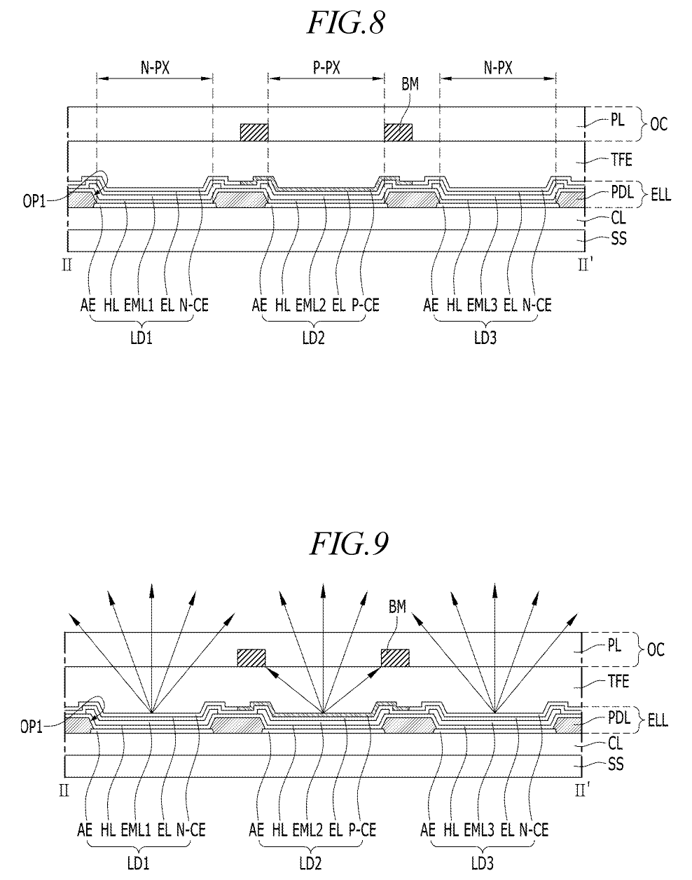

FIG. 8 is a cross-sectional view of the display panel taken along line II–II′ of FIG. 6. The light-emitting regions PXA-R, PXA-G, and PXA-B shown in FIG. 6 may correspond, respectively, to light-emitting diodes LD1, LD2, and LD3 shown in FIG. 8. The light-emitting diodes LD1, LD2, and LD3 may be included in the light-emitting diode layer ELL along with the pixel defining layer PDL. The light-emitting diodes LD1, LD2, and LD3 are disposed on the circuit layer CL and may each include an anode electrode AE, a hole control layer HL, an emission layer EML, an electron control layer EL, and cathode electrodes N-CE, and P-CE.

The anode electrode AE of each of light-emitting diodes LD1, LD2, and LD3 may be electrically connected to a transistor disposed in the circuit layer CL. The hole control layer HL may be disposed on the anode electrode AE to assist the movement of holes generated at the anode electrode AE. In an embodiment, the hole control layer HL may be structured to further include a hole injection layer and a hole transport layer, for example.

Each of the emission layers EML1, EML2, and EML3 may be disposed on the hole control layer HL and may emit light. The emission layers EML1, EML2, and EML3 may include organic light-emitting materials or quantum dots. Accordingly, the light-emitting diodes LD1, LD2, and LD3 may be organic light-emitting diodes (“OLEDs”) or quantum dot light-emitting diodes (“QLEDs”).

The electron control layer EL may be disposed on the emission layers EML1, EML2, and EML3 to assist the movement of electrons generated at the cathode electrodes N-CE, and P-CE. In an embodiment, the electron control layer EL may be structured to further include an electron injection layer and an electron transport layer, for example.

The cathode electrodes N-CE, and P-CE may be disposed on the electron control layer EL. In an embodiment, the cathode electrodes N-CE, and P-CE may include or consist of different materials depending on whether they correspond to a normal pixel N-PX or a private pixel P-PX. The cathode electrode N-CE of the normal pixel N-PX may have a higher transmittance than a transmittance of the cathode electrode P-CE of the private pixel P-PX. In an embodiment, the cathode electrode N-CE of the normal pixel N-PX may include a transparent conductive material such as indium tin oxide (“ITO”), indium zinc oxide (“IZO”), zinc oxide (ZnO), aluminum-doped zinc oxide (“AZO”), or indium oxide (In₂O₃), for example. In contrast, the cathode electrode P-CE of the private pixel P-PX may include at least one of silver (Ag) and magnesium (Mg). Therefore, by forming the cathode electrode N-CE of the normal pixel N-PX using a transparent conductive oxide, the viewing angle characteristics may be improved in a normal mode through a weak cavity effect between the anode electrode AE and the cathode electrode N-CE.

The first, second, and third light-emitting diodes LD1, LD2, and LD3 may emit light at different wavelengths from the emission layers EML1, EML2, and EML3, respectively. In an embodiment, the first light-emitting diode LD1 may emit red light, the second light-emitting diode LD2 may emit green light, and the third light-emitting diode LD3 may emit blue light, for example.

The pixel defining layer PDL may be disposed on the circuit layer CL and may include or consist of a polymer resin. Additionally, the pixel defining layer PDL may be formed to include a light-absorbing material or may include a black pigment or black dye, thereby implementing a black pixel defining layer.

The pixel defining layer PDL may define and separate individual pixels. A first opening OP1 that exposes at least a portion of the anode electrode AE may be defined in the pixel defining layer PDL. The hole control layer HL may be disposed on a portion of the anode electrode AE exposed through the first opening OP1, and the emission layers EML1, EML2, and EML3 may be disposed on the hole control layer HL. The emission layers EML1, EML2, and EML3 may be disposed within the first opening OP1. The cathode electrodes N-CE, and P-CE may be disposed on each of the emission layers EML1, EML2, and EML3, and may also be disposed on the entirety of the pixel defining layer PDL. In an embodiment, the cathode electrodes N-CE, and P-CE may include or consist of different materials depending on whether they correspond to a normal pixel N-PX or a private pixel P-PX.

An encapsulation layer TFE may be disposed on the light-emitting diode layer ELL and over the cathode electrodes N-CE, and P-CE. The encapsulation layer TFE may include at least one of an inorganic encapsulation layer and an organic encapsulation layer. The inorganic and organic encapsulation layers may have an alternating stacked structure. The encapsulation layer TFE may encapsulate the light-emitting diodes LD1, LD2, and LD3 to protect the light-emitting diodes LD1, LD2, and LD3 from external oxygen or moisture.

An overcoat layer OC may be disposed on the encapsulation layer TFE and may include a light-shielding unit BM and a planarization layer PL. The planarization layer PL may cover the light-shielding unit BM and may minimize step differences caused by the light-shielding unit BM. The planarization layer PL may include or consist of an organic insulating material. In an embodiment, the planarization layer PL may include polyacrylate resin, epoxy resin, phenolic resin, or polyamide resin, for example.

The light-shielding unit BM may be a black matrix and may include or consist of an organic or inorganic light-shielding material that includes a black pigment or dye. The light-shielding unit BM may include a light-blocking material and may define and separate individual pixels along with the pixel defining layer PDL. The light-shielding unit BM may be disposed over the second light-emitting diode LD2 corresponding to the private pixel P-PX, and an opening that exposes the light-emitting region may be defined in the light-shielding unit BM. Accordingly, when driven in the private mode and the private pixel P-PX is activated, light is emitted in a manner that reduces luminance from side views relative to the front.

FIG. 9 is a schematic illustration of an embodiment of a viewing angle of a display device according to the disclosure. As described with reference to FIGS. 6 through 8, in the case of a normal pixel, the light-emitting diodes LD1, LD2, and LD3 may emit light with a wide viewing angle. In contrast, in the case of a private pixel, the viewing angle of the light emitted from the light-emitting diodes LD1, LD2, and LD3 may be restricted by the light-shielding unit BM compared to that of the normal pixel. Accordingly, in the private mode, a display screen with reduced side visibility may be provided.

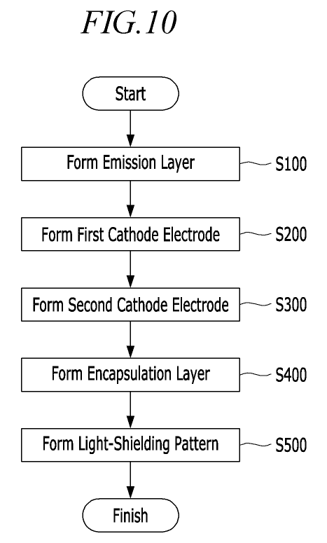

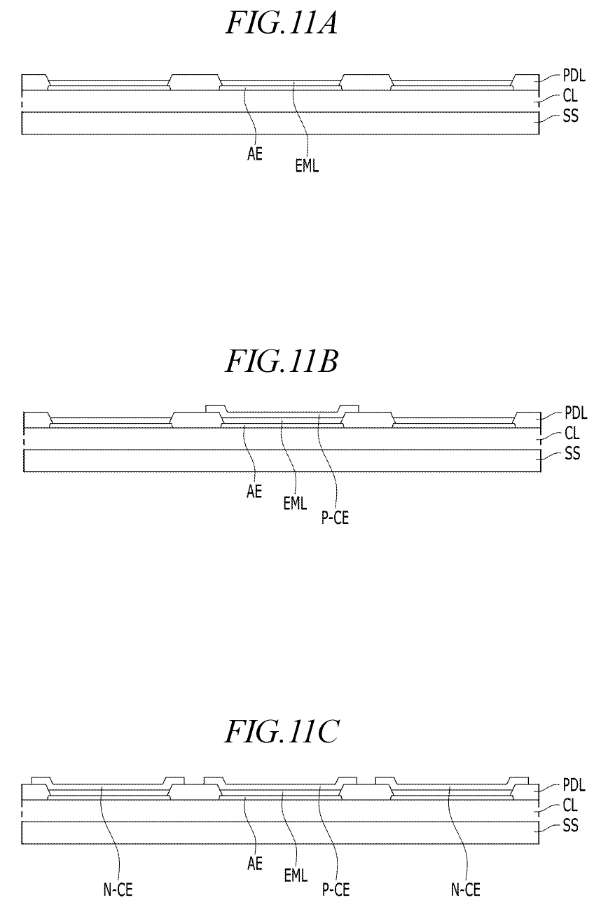

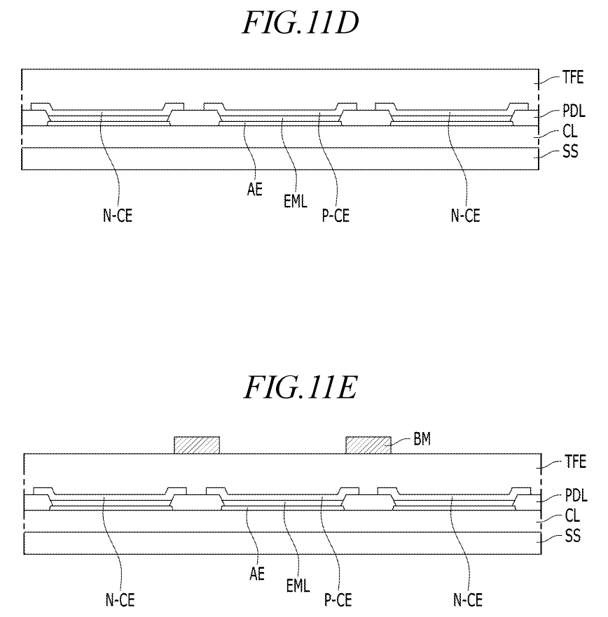

FIG. 10 is a flow diagram illustrating an embodiment of a method for manufacturing a display device according to the disclosure. FIGS. 11A through 11E are diagrams illustrating an embodiment of the method for manufacturing a display device according to the disclosure.

Referring to FIG. 10, the method for manufacturing the display device may include an operation (S100) of forming an emission layer, an operation (S200) of forming a first cathode electrode, an operation (S300) of forming a second cathode electrode, an operation (S400) of forming an encapsulation layer, and an operation (S500) of forming a light-shielding pattern.

Referring to FIGS. 10 and 11A, in the operation (S100) of forming an emission layer, an anode electrode AE and an emission layer EML may be formed on a display region of a circuit layer CL disposed on a substrate SS. Additionally, before the emission layer EML is formed, a pixel defining layer PDL exposing a portion of the anode electrode AE and overlapping the anode electrode AE may be formed. Although not illustrated, a hole control layer may be disposed on the anode electrode AE, and an electron control layer may be disposed on the emission layer EML.

Referring to FIGS. 10 and 11B in the operation (S200) of forming a first cathode electrode, a first cathode electrode P-CE may be formed on the emission layer EML corresponding to a private pixel in the display region. The first cathode electrode P-CE may be the cathode electrode of the private pixel. The operation (S200) of forming a first cathode electrode may include depositing the first cathode electrode P-CE including at least one of silver (Ag) and magnesium (Mg).

Referring to FIGS. 10 and 11C in the operation (S300) of forming a second cathode electrode, a second cathode electrode N-CE may be formed on the emission layer EML corresponding to a normal pixel in the display region. The second cathode electrode N-CE may be the cathode electrode of the normal pixel. The operation (S300) of forming a second cathode electrode may include depositing the second cathode electrode N-CE including at least one of indium tin oxide (“ITO”), indium zinc oxide (“IZO”), zinc oxide (ZnO), aluminum-doped zinc oxide (“AZO”), and indium oxide (In₂O₃). Accordingly, the second cathode electrode N-CE may have a higher transmittance than a transmittance of the first cathode electrode P-CE.

Through the operation (S200) of forming a first cathode electrode and the operation (S300) of forming a second cathode electrode, the private and normal pixels may be arternately arranged two-dimensionally and define the display region. In such a case, the operation (S200) of forming a first cathode electrode and the operation (S300) of forming a second cathode electrode are not limited to any particular order.

Referring to FIGS. 10 and 11D in the operation (S400) of forming an encapsulation layer, an encapsulation layer TFE including at least one of an inorganic film and an organic film may be formed on the first cathode electrode P-CE and the second cathode electrode N-CE. The encapsulation layer TFE may cover the first cathode electrode P-CE, the second cathode electrode N-CE, and the pixel defining layer PDL. The encapsulation layer TFE may include alternating stacks of multiple inorganic layers and organic layers.

Referring to FIGS. 10 and 11E in the operation (S500) of forming a light-shielding pattern, a light-shielding pattern BM overlapping the private pixel may be formed on the encapsulation layer TFE. An opening that exposes a light-emitting region of the private pixel may be defined in the light-shielding pattern BM. Accordingly, the viewing angle of the normal pixel may be wider than that of the private pixel.

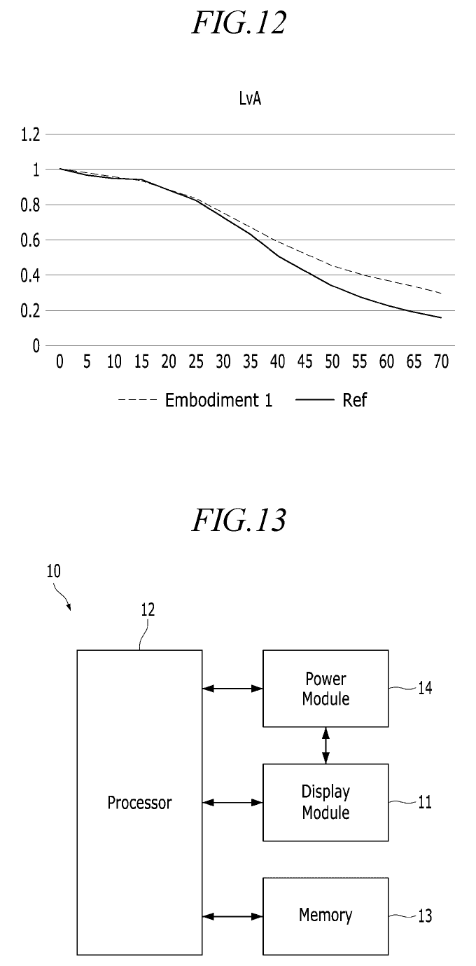

FIG. 12 is a graph showing an embodiment of luminance variation LvA according to a viewing angle of a display device according to the disclosure. The graph of FIG. 12 illustrates the luminance ratio based on the material of the cathode electrode of the normal pixel when the display device is driven in a normal mode. "Ref" represents the luminance ratio when the cathode electrode of the normal pixel includes or consists of silver (Ag) or magnesium (Mg), and "Embodiment 1" represents the luminance ratio when the cathode electrode includes or consists of a transparent conductive oxide. The horizontal axis and vertical axis represent the viewing angle and the luminance ratio, respectively. The luminance ratio may be defined as the ratio of luminance between the front and the side views.

When the viewing angle is 45º or greater, it may be seen that the luminance ratio of Embodiment 1 is improved by 10% or more compared to Ref. This indicates that, by applying a cathode electrode with relatively high transmittance, the amount of light transmitted through the cathode electrode from the emission layer increases. Accordingly, compared to a display device in which the cathode electrode of the normal pixel includes or consists of silver (Ag) or magnesium (Mg), the side-view luminance ratio in the normal mode may be improved. As a result, the luminance characteristics with respect to the side viewing angle of a display device that supports a private mode may be enhanced, thereby improving the overall display quality.

The display device in an embodiment of the disclosure may be applied to various electronic devices. An electronic device in an embodiment may include the display device described above and may further include modules or devices that provide additional functions beyond the display device.

FIG. 13 is a block diagram of an embodiment of an electronic device including a display device according to the disclosure. Referring to FIG. 13, an electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may have data information desired for operations of the processor 12 or the display module 11 stored therein. When the processor 12 executes an application stored in the memory 13, an image data signal and/or an input control signal may be transferred to the display module 11, which may then process the received signal and output image information via a display screen.

The power module 14 may include a power supply module, such as a power adapter or a battery device, and a power conversion module configured to convert power supplied from the power supply module into power desired for the operation of the electronic device 10.

At least one of the components of the electronic device 10 described above may be included within the display device in the embodiments described herein. Additionally, some of the individual modules functionally included within a single module may be included in the display device, while others may be provided separately from the display device. In an embodiment, the display device may include the display module 11, while the processor 12, the memory 13, and the power module 14 may be provided as components of another device within the electronic device 10, for example.

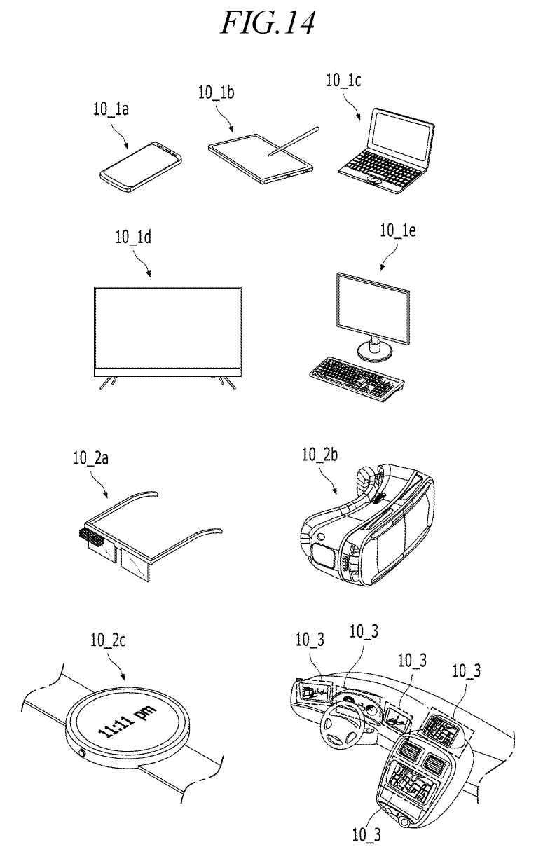

FIG. 14 illustrates various embodiments of electronic devices including a display device according to the disclosure. Referring to FIG. 14, various electronic devices to which the display device in the embodiments is applied may include: image-displaying electronic devices, such as a smartphone 10_1a, a tablet personal computer (“PC”) 10_1b, a laptop computer 10_1c, a television 10_1d, and a desktop monitor 10_1e; wearable electronic devices including a display module, such as smart glasses 10_2a, a head-mounted display 10_2b, and a smartwatch 10_2c; and automotive electronic devices 10_3 including a display module, such as a cluster instrument display, a center fascia, a dashboard-mounted center information display (“CID”), or a room mirror display.

While illustrative embodiments of the disclosure have been described herein, anyone ordinarily skilled in the art to which the disclosure pertains shall appreciate that there may be a variety of modifications and permutations of the disclosure without departing from the technical ideas and scopes of the disclosure that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A display device comprising:
a substrate;
a circuit layer disposed on the substrate;
a light-emitting diode layer disposed on the circuit layer, the light-emitting diode layer comprising:
a first emission layer corresponding to a first pixel unit; and
a second emission layer corresponding to a second pixel unit;
an encapsulation layer disposed on the light-emitting diode layer, the encapsulation layer comprising:
at least one of an inorganic film and an organic film; and
a light-shielding unit disposed on the encapsulation layer, overlapping the second pixel unit and exposing a light-emitting region of the second pixel unit, the light-emitting diode layer comprising:
a first anode electrode corresponding to the first pixel unit and disposed between the circuit layer and the first emission layer;
a first cathode electrode corresponding to the first pixel unit and disposed on the first emission layer;
a second anode electrode corresponding to the second pixel unit and disposed between the circuit layer and the second emission layer; and
a second cathode electrode corresponding to the second pixel unit and disposed on the second emission layer, and
wherein the first cathode electrode has a higher transmittance than a transmittance of the second cathode electrode.

2. The display device of claim 1, wherein the first cathode electrode comprises at least one of indium tin oxide, indium zinc oxide, zinc oxide (ZnO), aluminum-doped zinc oxide, and indium oxide (In₂O₃).

3. The display device of claim 1, wherein the second cathode electrode comprises at least one of silver (Ag) and magnesium (Mg).

4. The display device of claim 1, wherein a viewing angle of the first pixel unit is wider than a viewing angle of the second pixel unit.

5. The display device of claim 1, wherein an opening which exposes the light-emitting region of the second pixel unit is defined in the light-shielding unit, and
wherein the opening of the light-shielding unit has a shape including at least one of circular, elliptical, and polygonal shapes.

6. The display device of claim 1, wherein the light-shielding unit comprises a plurality of light-shielding patterns stacked in a direction of display.

7. An electronic device comprising:
a display module comprising:
a display panel comprising:
a first pixel unit comprising:
a first anode electrode;
a first emission layer; and
a first cathode electrode;
a second pixel unit comprising:
a second anode electrode;
a second emission layer; and
a second cathode electrode; and
a driving circuit electrically connected to the first pixel unit and the second pixel unit,
wherein the driving circuit is configured to activate the first pixel unit and the second pixel unit in a first operation mode and to deactivate the first pixel unit and activate the second pixel unit in a second operation mode, and
wherein the first cathode electrode has a higher transmittance than a transmittance of the second cathode electrode.

8. The electronic device of claim 7, wherein the first cathode electrode includes at least one of indium tin oxide, indium zinc oxide, zinc oxide (ZnO), aluminum-doped zinc oxide, and indium oxide (In₂O₃).

9. The electronic device of claim 7, wherein the second cathode electrode includes at least one of silver (Ag) and magnesium (Mg).

10. The electronic device of claim 7, wherein a viewing angle of the first pixel unit is wider than a viewing angle of the second pixel unit.

11. The electronic device of claim 7, wherein the first pixel unit and the second pixel unit are alternately arranged two-dimensionally and define a display region of the display panel.

12. The electronic device of claim 7, further comprising:
a processor configured to execute an application to transfer an image data signal to the display module;
a memory in which data information for executing the application is stored; and
a power module configured to supply power to the display module, the processor, and the memory,
wherein the display module is configured to output image information based on the image data signal.

13. A method for manufacturing a display device, the method comprising:
forming an anode electrode and an emission layer on a display region of a circuit layer;
forming a first cathode electrode on the emission layer corresponding to a first region of the display region;
forming a second cathode electrode on the emission layer corresponding to a second region of the display region different from the first region;
forming an encapsulation layer comprising at least one of an inorganic film and an organic film on the first cathode electrode and the second cathode electrode; and
forming a light-shielding pattern on the encapsulation layer, the light-shielding pattern overlapping the second region and exposing a light-emitting region of the second region,
wherein the first cathode electrode has a higher transmittance than a transmittance of the second cathode electrode.

14. The method of claim 13, wherein the forming the first cathode electrode includes depositing the first cathode electrode comprising at least one of indium tin oxide, indium zinc oxide, zinc oxide (ZnO), aluminum-doped zinc oxide, and indium oxide (In₂O₃).

15. The method of claim 13, wherein the forming the second cathode electrode comprises depositing the second cathode electrode comprising at least one of silver (Ag) and magnesium (Mg).

16. The method of claim 13, wherein the forming the first cathode electrode is performed before the forming the second cathode electrode.

17. The method of claim 13, wherein the forming the second cathode electrode is performed before the forming the first cathode electrode.

18. The method of claim 13, wherein the first region and the second region are alternately arranged two-dimensionally in the display region.

19. The method of claim 13, wherein the light-shielding pattern provides an opening which exposes the light-emitting region of the second region, and
wherein the opening of the light-shielding pattern has a shape including at least one of circular, elliptical, and polygonal shapes.

20. The method of claim 13, wherein a viewing angle of the first region is wider than a viewing angle of the second region.
